(19) United States
(12) Patent Application Publication
(10) Pub. No.: US 2014/0268582 A1
(43) Pub. Date: Sep. 18, 2014

(54) ELECTRONIC DEVICE ENCLOSURE SYSTEM AND METHOD

(71) Applicant: Ergotron, Inc., St. Paul, MN (US)

(72) Inventors: Thiem Wong, Minneapolis, MN (US); David J. Prince, Saint Paul, MN (US)

(73) Assignee: Ergotron, Inc., St. Paul, MN (US)

(21) Appl. No.: 14/208,212

(22) Filed: Mar. 13, 2014

Related U.S. Application Data
(60) Provisional application No. 61/778,700, filed on Mar. 13, 2013.

(51) Int. Cl. H05K 7/16; H05K 5/02

(52) U.S. Cl. CPC H05K 7/16; H05K 5/0239; H05K 5/0247
USPC 361/727; 312/329

(57) ABSTRACT

An enclosure for storing more than one electronic device. The enclosure includes a frame having a rear surface to be in apposition to a support surface, a rack supported within the frame, the racking having at least one slot for receiving an electronic device, and a door supported by the frame and pivotable about a generally vertical axis between a closed position substantially perpendicular to the rear surface and an open position substantially planar with the rear surface, the slot being accessible through a side of the enclosure when the door is in the open position.

### CLAIM OF PRIORITY

This application claims the benefit of priority under 35 U.S.C. §119(e) of U.S. Provisional Patent Application Ser. No. 61/778,700, filed on Mar. 13, 2013, which is herein incorporated by reference in its entirety.

This disclosure generally relates to an enclosure for storing and networking mobile electronic devices.

### BACKGROUND

Mobile electronic devices, such as tablet computing devices, are generally planar, lightweight devices that include a touch-screen display. Examples include the Apple iPad, Kindle Fire, Motorola Xoom, Samsung Galaxy, Blackberry Playbook, LG Optimus Pad, Dell Streak, HP TouchPad, HTC Flyer, and Viewsonic ViewPad. Generally, tablets have a rectangular form factor that may be considered smaller than a traditional laptop or desktop computer monitor but larger than a smaller electronic device such as a smartphone. For example, in some cases tablets may be about 20 CM to about 30 CM in length, about 10 CM to about 20 CM in height, and about 1 CM in thickness or less, with a weight of between about 400 grams and about 1 KG. Tablets also generally have a display panel (e.g. LCD or TFT) with a screen size of between about 15 CM and about 25 CM, and may include a variety of other features such as front and/or rear camera(s), wire or cable connector(s) (e.g., proprietary, HDMI, USB, audio, charging/power, etc.), and wireless network connections (e.g., 3G/4G, Wi-Fi). Tablets may also currently have between about 500 MB and about 1 GB of RAM and between about 16 GB and about 64 GB of storage memory.

A typical tablet 10 is depicted in FIGS. 1-2 with an optional fold-over cover 12. As shown, tablet 10 can have any number of tablet ports 14, which can include a power port 16, a USB port 18, a network port 20, in and out audio ports 22, a video port 24 and a proprietary port 26.

Given that tablets are generally rectangularly shaped, tablets are thus typically symmetrical when viewed front-on, as shown in FIG. 1. When viewed end on, as shown in FIG. 2, some tablets are not symmetrically shaped about a center line 28. In the example shown, the front face 30 is slightly wider than the back plate 32, which results in the asymmetrical feature 34. Tablets can also have many other asymmetrical features, which may also distinguish the front face 30 from the back plate 32 of a tablet when viewed end on, as shown in FIG. 2. Such asymmetrical features can be in the form of one or more edges that are beveled, one or more edges that have a larger radius than other edges, or any other asymmetrical feature to distinguish the front from the back when the tablet is viewed end on.

Tablet users often choose to cover their tablets with a tablet cover 12, as depicted in FIG. 1. As can be appreciated, tablet covers can protect tablets from dust, abrasions, scratches and the like, however, tablet covers also can change the overall outside linear dimensions of a tablet. In addition, as tablets can have asymmetrical features, the addition of a cover can render such an asymmetrical feature unsuitable or unusable for distinguishing the front face from the back plate of a tablet.

Other electronic devices include cellular phones, smart phones, music players (e.g. mp3 player), and cameras.

### SUMMARY

Embodiments of an enclosure configured for storing and/or securing one or more electronic devices are disclosed. One or more embodiments of the enclosure include one or more racks having at least one to receive electronic devices. Each rack and/or slot can be configured for receiving the one or more devices into or within the enclosure for storing the one or more devices. In some embodiments the rack and/or slots are configured to receive a device from a generally lateral direction. In some embodiments, access to the slots is obstructed except for access by a lateral side. For example, the enclosure, rack, and/or slot may obstruct access from the top, bottom, front, and back and the right or the left side, but not both the right and the left sides.

Certain embodiments of the enclosure include one or more doors operable between a closed position and an open position. The one or more devices can be secured with the enclosure when the one or more doors is in the closed position. In some embodiments, the doors are configured to rotate about a generally vertical axis and to not break a plane defined by the front of the enclosure as they are rotated about the generally vertical axis. In certain embodiments, the doors are shaped such that they form a side of the enclosure when closed and are parallel to a surface supporting the enclosure when rotated about the generally vertical axis to a fully opened position. Such doors are useful for conserving space within a room compared with doors that swing inward into the room from an enclosure.

In certain embodiments, the enclosure includes at least one coupling associated with or connected to at least one of the doors and at least one of the racks. Each coupling can be configured for retracting the rack associated therewith into the enclosure when the door associated therewith is closed, and extracting at least a portion of the rack associated therewith out of the enclosure when the door associated therewith is opened. The movement of the rack can be linear and in a plane parallel to a surface supporting the enclosure. In such embodiments, the rack can extend outward of the enclosure as the door is opened to provide greater accessibility to the stored devices.

These and various other features and advantages will be apparent from a reading of the following detailed description.

### BRIEF DESCRIPTION OF THE DRAWINGS

The following drawings are illustrative of particular embodiments of the invention and therefore do not limit the scope of the invention. The drawings are not necessarily to scale (unless so stated) and are intended for use in conjunction with the explanations in the following detailed description. Embodiments of the invention will hereinafter be described in conjunction with the appended drawings, wherein like numerals denote like elements.

FIG. 1 is a front view of a tablet and a tablet cover;

FIG. 2 is an end view of the tablet of FIG. 1;

FIG. 3 is a front perspective view of an electronic device storage enclosure in accordance with an embodiment;

FIG. 4 is a front elevation view of the enclosure of FIG. 3;

FIG. 5 illustrates the enclosure of FIG. 4 with open doors and electronic devices extending out of the enclosure;

FIG. 6 is a front perspective view of the enclosure of FIG. 5 with the front cover removed;

FIG. 7 is a partial front perspective view of the enclosure of FIG. 6;

FIG. 8 is a partial side view of the interior at the bottom of the enclosure of FIG. 6;

FIG. 9 is a partial side view of the interior at the top of the enclosure of FIG. 6;

FIG. 10 is a front perspective view of an electronic device rack in accordance with an embodiment;

FIG. 11 is a front perspective cutaway view of a slot with connectors in accordance with an embodiment;

FIG. 12 is a front perspective cutaway view of a slot with connectors in accordance with an embodiment;

FIG. 13 is a front perspective cutaway view of a slot with connectors in accordance with an embodiment;

FIG. 14A is a front perspective cutaway view of a slot with connectors in accordance with an embodiment;

FIG. 14B is a top-front perspective cutaway view of a storage slot with connectors in accordance with an embodiment;

FIG. 15A is an electrical block diagram in accordance with an embodiment;

FIG. 15B is an electrical block diagram in accordance with an embodiment;

FIG. 15C is an electrical block diagram in accordance with an embodiment;

FIG. 15D is an electrical block diagram in accordance with an embodiment;

FIG. 16A is a network block diagram in accordance with an embodiment;

FIG. 16B is a network block diagram in accordance with an embodiment;

FIG. 16C is a network block diagram in accordance with an embodiment; and

FIG. 16D is a network block diagram in accordance with an embodiment.

### DETAILED DESCRIPTION

The following detailed description is exemplary in nature and is not intended to limit the scope, applicability, or configuration of the invention in any way. Rather, the following description provides some practical illustrations for implementing exemplary embodiments of the present invention. Examples of constructions, materials, dimensions, and manufacturing processes are provided for selected elements, and all other elements employ that which is known to those of ordinary skill in the field of the invention. Those skilled in the art will recognize that many of the noted examples have a variety of suitable alternatives.

Embodiments described herein provide systems, devices, and methods for storing and/or charging and/or networking one or more electronic devices, such as tablets. Some embodiments provide an electronic device storage enclosure having one or more electronic device racks for storing, charging, and/or networking one or more electronic devices. In some embodiments, the enclosure includes a frame with a rear surface adapted to be in apposition to or attached to another surface, such as a stationary support surface. Examples of such stationary surfaces can include vertical surfaces, horizontal surfaces, and surfaces at other angles, including surfaces of a wall, a column.

In some embodiments, the enclosure can include one or more electronic device racks with one or more slots adapted to hold at least one electronic device. In some embodiments, the enclosure, rack, and/or slot are configured to allow access to the slot from a lateral direction (i.e., the left or right side, such as only the left or right side). Each rack can be configured to hold as many electronic devices as desired. For example, in some cases each rack may hold one, ten, twenty, thirty, fifty, or any number of electronic devices. In certain embodiments, the enclosure has one or more doors, such as doors with a space-saving configuration.

In certain embodiments, the electronic device racks can be retracted into the enclosure for storing and securing the one or more electronic devices placed in the slots of the storage rack, and at least a portion of each electronic device rack can be extended out of the enclosure for accessing the electronic devices.

FIGS. 3-6 illustrate various views of electronic device storage enclosure 100 in different stages of use. As shown, enclosure 100 can include a frame 102 of a predefined thickness for housing one or more electronic devices 104. Enclosure 100 can also include one or more doors 106 through which the electronic devices 104 can be retracted into or extracted from enclosure 100. As shown, in some embodiments the doors are configured to rotate about a generally vertical axis and to not break a plane defined by the front of the enclosure as they are rotated about the generally vertical axis. In certain embodiments, the doors are shaped such that they form a side of the enclosure when closed and are parallel to a surface supporting the enclosure when rotated about the generally vertical axis to a fully opened position. Such doors are useful for conserving space within a room compared with doors that swing inward into the room from an enclosure

In the embodiment illustrated in FIGS. 3-6 (and also FIGS. 7-9), the electronic devices 104 can be retracted into or extracted from both the left and the right side of the enclosure 100. The enclosure 100 can also be configured for retracting or extracting the electronic devices 104 from only one of the two sides of the enclosure 100. In a non-limiting exemplary embodiment of enclosure 100, at least one longitudinally extending edge of each of the one or more doors 106 is configured or adapted for rotational movement about a vertical axis along a corresponding longitudinally extending edge of the rear of frame 102 of enclosure 100. In such an embodiment, the door is aligned with the rear of the enclosure and parallel to a support surface supporting the enclosure when it is opened, allowing access to the interior of the enclosure. In some embodiments, the enclosure includes a door supported by the frame and pivotable about a generally vertical axis between a closed position substantially perpendicular to the rear surface of the frame and an open position substantially planar with the rear surface.

In some embodiments, each one of the one or more doors 106 can have a corresponding (or associated) door lock 108 for locking the doors 106 and securing the electronic devices 104 within enclosure 100.

As shown, certain embodiments of enclosure 100 can include front cover 110 having optional vents 112 to facilitate sufficient air circulation through the enclosure 100 to facilitate cooling of stored electronic devices 104. In a non-limiting exemplary embodiment, front cover 110 can be slidably removed, as illustrated in FIG. 6, for providing access to the devices and components, e.g., wiring, connectors, etc., within the interior of enclosure 100 as described in further detail below with reference to FIGS. 11-14B. In certain embodiments, front cover 110 can include a door with or without a lock. In some embodiments, enclosure 100 can include front compartment 114 accessible via the front cover, which will be described in further detail below.

Certain embodiments of enclosure 100 include light 116 and/or one or more banks of lights 118 on front panel 120. In certain embodiments, light 116 can be used for indicating whether or not power cable 122, extending from enclosure 100, is supplying electrical power to the components and devices within enclosure 100. In some embodiments, each light in the one or more banks of lights 118 can be associated with one of the slots of the electronic device storage rack. As such, each light can be used for indicating which slots have electronic devices placed therein, and which of those electronic devices are being charged and/or are fully charged.

As shown in FIGS. 3-6, the enclosure 100 can include a rack 124 with a plurality of slots 130 configured to receive an electronic device 104. In some embodiments the rack and/or slots are configured to receive a device from a generally lateral direction. In some embodiments, access to the slots is obstructed except for access by a lateral side. For example, the enclosure, rack, or slot may obstruct access from the top, bottom, front, and back and the right or the left side, but not both the right and the left side.

In some embodiments, a door and rack can be coupled together to position electronic devices stored within the rack in an easy accessible position. In the interest of brevity, the configuration and operation of an embodiment of only one paired set of door 106 and electronic device rack 124 is described in the following with reference being made to FIGS. 7-9. In accordance with an embodiment of the invention, enclosure 100 includes a coupling 126 for facilitating the coupled movement of a rack 124 and a corresponding door 106. It should be noted that FIGS. 7-9 illustrate only small portions or sections of the described components. For instance, FIG. 7 is a partial perspective view of a portion of the bottom left corner of enclosure 100 when viewed from the front; FIG. 8 is a cross-sectional view of a portion of the bottom section of enclosure 100 when view from a side thereof; and FIG. 9 is a cross-sectional view of a portion of the top section of enclosure 100 when view from a side thereof.

FIG. 7 illustrates an embodiment of the coupling 126. As illustrated, coupling 126 includes an elongated link bar 132 which is connected at its first end to rack 124 for rotational movement about pivot point 134, and is connected at its second end to door 106 for rotational movement about pivot point 136. In some embodiments, the rack travels substantially linearly in a plane parallel to the rear surface of the enclosure frame. For example, rack 124 can include a longitudinally extending groove 138 proximate its rear section 140, and a mating ridge 142 extends longitudinally along the inside of enclosure 100. The longitudinally extending groove 138 and the longitudinally extending ridge 142 are configured as mating components wherein their respective contours are substantially similar. As such, the combination of the groove 138 and the ridge 142 functions as a guide for the longitudinal movement of the rack 124 when the groove 138 is placed over and straddles the ridge 142. The combination of the groove 138 and the ridge 142 restricts the rack 124 to longitudinal movements only. A longitudinally extending hinge 144 rotatably couples the frame 102 of enclosure 100 and the door 106 to one another along at least one of their respective edges. As such, relative to the enclosure 100 (or frame 102), the door 106 can be rotated about the axis of the hinge 144 in the directions of the arrows designated with reference numeral 146 so as to open or close the corresponding side of enclosure 100.

In the embodiment shown, coupling 126 in combination with the mating groove 138 and ridge 142 defines a configuration wherein the rotational movement of the door 106 imparts a longitudinal movement of the rack 124 in the directions of the arrows designated with reference numeral 148. By way of example, and as illustrated in FIG. 7, a clockwise rotation of the door 106 for opening the corresponding side of the enclosure 100 will impart, through link bar 132, a pulling force on the rack 124 so as to extract the rack 124 out of the enclosure 100. Conversely, a counter-clockwise rotation of the door 106 for closing the corresponding side of the enclosure 100 will impart, through link bar 132, a pushing force on the rack 124 so as to retract the rack 124 into the enclosure 100. Therefore, it can be seen that when the rack 124 includes one or more electronic devices 104 placed in the slots 130 thereof, then the clockwise rotation of the door 106 will pull the tablets 104 that are in the slots 130 of the rack 124 out of the enclosure 100. Conversely, the counter-clockwise rotation of the door 106 will push the electronic devices 104 that are in the slots 130 of the rack 124 into the enclosure 100 at which stage the lock 108 can be used to secure the door 106 to the enclosure 100, thereby denying access to the electronic devices 104 there within.

Although not illustrated in FIG. 7 or 8, the rack 124 can include one or more additional configurations for providing stability and support both during its longitudinal movements into and out of the enclosure 100 and/or when at rest within and/or outside the enclosure 100. For instance, in a non-limiting exemplary embodiment, the rack 124 can include an additional pair of mating groove and ridge and/or a roller rail system as is well known in the art. In some embodiments of enclosure 100, one or more such additional or alternate configurations can be proximate a front section (opposite the rear section 140) of the rack 124.

The embodiments of the rack 124 and the slots 130, at least a portion which are illustrated in FIG. 8, are described in further detail below. FIG. 8 also illustrates some of the components 150 housed within interior space 152 of front compartment 114. Typical components 150, such as power systems, electrical devices, battery charging system, network connectivity components, etc., are also described in further detail below. Of course, some or all of the components 150 can also be housed within the same interior space of enclosure 100 as the electronic devices 104.

As illustrated in FIGS. 8 and 9, the rack 124 can include a rear frame 154 defining the perimeter of a rear plane. In some embodiments of enclosure 100, the edge of the rear section 140 of the rack 124 defines the bottom edge or side (not shown) of the rear frame 154 extending away, in this case upwards, from the rack 124. In addition to, or in the alternative, some embodiments of enclosure 100 can include a front frame 156 defining the perimeter of a front plane. In the illustrated embodiment of enclosure 100, the edge of the front section (opposite the rear section 140) defines the bottom edge or side (not shown) of the front frame 156 extending away, in this case upwards, from the rack 124. As such, the front and/or the rear frames 156 and 154, respectively, can provide support along the perimeter of the rack 124.

It will be appreciated that rack 124 can provide at least some degree of support and stability along the bottom edges (or sides) of the front and/or rear frames 156 and 154, respectively. In some embodiments of enclosure 100, such support and stability accorded solely by the rack 124 can be sufficient and no additional support and/or stability may be useful. However, in certain embodiments of the enclosure 100, it may be useful to provide additional support for the rack 124 and/or the front and/or rear frames 156 and 154, respectively. To that end, FIGS. 8 and 9 illustrate an embodiment of enclosure 100 having one or more additional supports 158 within the enclosure 100. In some embodiments of enclosure 100, the one or more supports 158 can be on the inside surface of the front cover 110 and/or the rear panel 160. In certain embodiments of enclosure 100, the one or more supports 158 can be a pair of mating groove and ridge (e.g., 138 and 142), a roller rail system, an engaged pair of opposing channels, or any other application appropriate components and/or system, including combinations of one or more of those listed.

While FIG. 7 illustrates the coupling 126 operationally attaching or connecting a bottom of the door 106 to the rack 124, this does not always have to be the case. For instance, in a non-limiting exemplary embodiment of enclosure 100, the coupling 126 can be operationally attached or connected to the door 106 and the rack 124 at the top of the enclosure 100. In some embodiments, the coupling 126 can be operationally attached or connected to the door 106 and the rack 214 at both at the top and at the bottom of the enclosure 100. In some embodiments, the coupling 126 can be operationally attached or connected to the door 106 and either one or both of the front and rear frames 156 and 154. In certain embodiments, such attachment or connection between the door 106 and the front and/or rear frames can be at the top and/or at the bottom and/or at any location between the top and the bottom.

FIG. 10 depicts an embodiment of a rack 124 having a frame 162 which includes five slots 130. As shown, slots 130 can be arranged in a substantially vertical orientation in rack 124 such that electronic devices 104 can be stored in a substantially vertical orientation. Also as shown, the slots can be at least partially overlapping. Slots 130 can include any shape that is useful for holding an electronic device 104 in such a generally vertical orientation, which can include holding an electronic device 104 on one of its four edges (the top, bottom, left and right edges when the screen of the electronic device is viewed). Electronic devices 104 can also be held at a slight angle to a vertical, which can range from about 10 degrees to about 30 degrees from vertical. Each slot can be open at a side for inserting or removing electronic device.

As mentioned above, in some embodiments, connector(s) useful for connecting one or more stored electronic devices 104 to a power supply system and/or network connection system can be disposed in one or more of the slots 130. Such connector(s) can be applicable to one or all of the embodiments described herein. FIGS. 11-14B provide perspective cutaway views of a number of storage slots 130 with various connector configurations in accordance with some embodiments. In some cases the connectors can be pigtail connection connectors 164, as shown in FIGS. 11-13, or connectors 166 that are part of a docking station 168, as shown in FIGS. 14A and 14B. Each connector 164, 166 can connect an associated electronic device 104 with, for example, the enclosure's power supply system and/or network connection system when the electronic devices 104 are stored and connected.

In the embodiments that use a docking station 168, the docking station connector 166 connects to the electronic device 104 automatically as the electronic device is positioned (e.g. pushed in) into the storage and connection position. In some embodiments, the connector(s) within a slot 130 can be located to one side of the storage and connection slot 130, as discussed in greater detail below. Further, in some cases the connectors may be integrated within a tray-shaped docking station that is positioned within a storage slot 130.

In some embodiments that use a pigtail connection connector 164, individual storage and connection slots 130 may in some cases be used by more than one type (e.g., brand and/or model) of electronic device, depending on the compatibility of the connector itself with respect to a particular electronic device type. In some embodiments that use a docking station connector 166, the docking station 168 along with the docking station connector(s) 166 may optionally be removable so that they can be removed and replaced by another docking station 168 that has a configuration and docking station connector(s) 166 that are adapted for use with another type of electronic device. Similarly, pigtail connection connectors 164 that are adapted for a proprietary connector and pin arrangement can be removed and replaced by another pigtail connection connector 164 that is adapted for use with another type of electronic device, or with a connector that is compatible with a variety of electronic device types.

Continuing with reference to FIGS. 11-14B, slots 130 generally include a front wall (not shown), a back wall 170, and a basal wall 172, and are open for access on at least one side. For the purposes of illustration, the front wall for any of the slot 130 is not shown in FIGS. 11-14B.

In some embodiments, the front wall of a slot 130 can be in an overlapping configuration with the front wall of an adjacent slot 130 in order to overlap at least a portion of the electronic devices 104 when stored. This configuration can reduce the vertical footprint of the rack 124. In some embodiments, the front wall can be angled 10-35 degrees from the back wall 170.

For embodiments that use a docking station 168, the slot 130 can include any shape useful for automatically guiding the electronic device into the slot and for aligning the electronic device port(s) 174 to engage with the docking station connector(s) 166. Docking station connector(s) 166 can be coated with a highly conductive material, that can be applied in a relatively thick coating (for example, 50 microinchs of gold (about 0.00127 mm)) to protect against wear from repeated insertions and extractions. In determining appropriate slot geometry, consideration of any asymmetrical feature 34 of the electronic device can be useful to ensure that the port(s) 174 engage correctly with the docking station connector(s) 166.

FIGS. 11-14B show various embodiments of pigtail connection connectors 164 and docking station connectors 166 within a slot 130. In some embodiments, pigtail connection connector(s) 164 can be used, as depicted in FIGS. 11-13. As shown in FIG. 13, the pigtail connection connectors 164, can enter the slot 130 through the basal wall 172. In such configurations, it may be desirable to provide risers 176 so that the electronic device weight does not rest on the wires coming out of the back of the connector, as doing so may eventually lead to a broken wire within the pigtail.

In some embodiments, a docking station connector 166 may be located on one of the innermost side of the slot 130. In such an embodiment, as depicted in FIG. 14A, storing and connecting an electronic device 104 would require disposing an electronic device 104 within a slot 130 and sliding the electronic device to the left in order to engage the port(s) 174 with the docking connector(s) 166. Again, as with other embodiments that make use of a docking station 168, the slot 130 can include any shape useful for automatically guiding an electronic device 104 into proper alignment so that the port(s) 174 engage with the docking station connector(s) 166. In the case of this embodiment the slot shape must be adapted so that the port(s) 174 engages with the docking station connector(s) 166, the when the electronic device 104 is moved to the left. Of course another embodiment where the port(s) 174 engages with the docking station connector(s) 166 when the electronic device 104 is moved to the right, should be equally apparent. Regardless of a particular physical configuration, in some cases a storage enclosure 100 can include a power supply system for charging a plurality of electronic devices 104 when stored.

FIGS. 15A-15D illustrate embodiments of some possible power supply systems that can be included in any of the embodiments discussed herein. The power supply system is useful for charging the electronic device batteries, and can also be used to power network connectivity equipment such as a wireless access point or a wired router, which are discussed below. In some cases, the power supply system is located internally to the enclosure 100 and not easily accessible to users.

In some embodiments, the power supply system can include a power cable 122, and a wall plug 178 that extends from an enclosure 100 to a wall outlet, as depicted in the block diagram of FIG. 15A. Such embodiments of the power supply system can be included in any of the enclosure embodiments discussed herein. In some embodiments, the power supply system can include a power cable 122 that extends from the enclosure 100 to form a junction with a building power-supply wire, as depicted in the block diagram of FIG. 15B. Such embodiments of the power supply system can be included in any of the enclosure embodiments discussed herein.

Embodiments of the power supply system convert AC power to DC power and ultimately route the power to each electronic device 104 stored in the enclosure 100. In some embodiments, the power supply system includes a timer, or other arrangement, that charges a subset of the total number of stored electronic devices 104 at any one time, and can cycle the subsets until all electronic devices 104 are substantially fully charged. Such a timer or other system, is useful for limiting the instantaneous power draw of the power supply system. In some embodiments, the power supply system can include an auxiliary outlet 180 located on the rack so that other devices, such as accessories, can be conveniently plugged in and provided with AC or DC power.

In some embodiments, the power supply system can include a combined power supply 182 which has a plurality of wires 184 that provide power to each stored electronic device 104, as depicted in the block diagram of FIG. 15C. In some embodiments, the power supply system can include a plurality of individual power supplies 186, each having a wire 184 that provides power to each stored electronic device 104, as depicted in the block diagram of FIG. 15D. In some embodiments that use individual power supplies 186, the number of electronic device 104 that are stored and connected to the power supply system can be limited so that the overall combined power demanded from the stored electronic devices 104 does not exceed the capacity available, either from a direct junction to a building power-supply wire, or from a standard wall outlet.

As depicted in the block diagrams of FIGS. 16A-16D, a network connection system can be provided for connecting a plurality of electronic devices 104 to a network such as the Internet and/or a Local Area Network. Such embodiments of the network connection system can be included in any of the embodiments of enclosure 100 discussed herein. In some cases, the network connection system is housed with the electronic devices 104 within the enclosure 100 and/or within the front compartment 114. As such, the network connection system is not easily accessible to users.

In some embodiments, as depicted in the block diagrams of FIGS. 16A-16D, the network connection system can include a device for the stored electronic devices 104 to communicate with a network. In general, the device can be configured for wired and/or wireless communication with one or more of the stored electronic devices 104 and/or the Internet and/or a Local Area Network. In some embodiments, the network connection can include a cable 188 extending from the device within the enclosure 100, as depicted in FIG. 16A. In some embodiments, the enclosure 100 can include a wireless receiver 190 that allows the electronic devices 104 to communicate with the network, as depicted in FIG. 16B. In some embodiments, as depicted in the block diagrams of FIGS. 16C-16D, the network connection system can include a device within the enclosure 100 for communicating with a plurality of the stored electronic devices 104. The network connection from the device to a plurality of stored electronic devices 104 can include a wired or wireless connection to each electronic device 104. As depicted in FIG. 16C, the device within the enclosure 100 is a wired router 192 with individual wires 194 to each of the stored electronic devices 104. As depicted in FIG. 16D, the device within the enclosure 100 is a wireless router 196 for wireless network connection to a plurality of stored electronic devices 104. As previously described with reference to FIGS. 16A and 16B, each of the wired routers 192 and/or wireless routers 196 can in turn be configured for wired and/or wireless communication with the network such as the Internet and/or a Local Area Network. Accordingly, any one or more of the network connections devices 190, 192 and 196 can be configured as a Wi-Fi access point, which can also be referred to as a Wi-Fi transmitter, a Wi-Fi receiver, a Wi-Fi transceiver, a Wi-Fi router, or by other similar terms. A wireless transmitter can provide wireless access to a network, which can be used by stored electronic devices 104, and by electronic devices that are in use by a user within the operating radius of the transmitter. Of course wireless technology other than Wi-Fi is also possible, depending on the preferences of a user, the capabilities of the electronic devices, and the wireless protocols that are commercially available, or in use.

Thus, some embodiments of the invention are disclosed. Although the invention has been described in considerable detail with reference to certain disclosed embodiments, the disclosed embodiments are presented for purposes of illustration and not limitation and other embodiments of the invention are possible. One skilled in the art will appreciate that various changes, adaptations, and modifications may be made without departing from the spirit and scope of the invention.

What is claimed is:

1. An enclosure for storing more than one electronic device, comprising:
a frame having a rear surface to be in apposition to a support surface;
a rack supported within the frame, the racking having at least one slot for receiving an electronic device; and
a door supported by the frame and pivotable about a generally vertical axis between a closed position substantially perpendicular to the rear surface and an open position substantially planar with the rear surface, the slot being accessible through a side of the enclosure when the door is in the open position.

2. The enclosure of claim 1, comprising a coupling connected to the door and to the rack, the coupling configured for retracting the rack into the enclosure when the door is closed and extracting at least a portion of the rack out of the enclosure when the door is opened, the rack traveling substantially linearly in a plane parallel to the rear surface.

3. The enclosure of claim 1, including more than one slot, wherein the slots are at least partially overlapping.

4. The enclosure of claim 1, wherein the at least one slot is configured to receive a device from a generally lateral direction.

5. The enclosure of claim 1, wherein access to the at least one slot is obstructed except for access by a lateral side.

6. The enclosure of claim 1, wherein the one or more electronic devices can be secured within the enclosure when the door is in the closed position.

7. The enclosure of claim 1, wherein the door is configured to rotate about a generally vertical axis and to not break a plane defined by the front of the enclosure as the door is rotated about the generally vertical axis.

8. The enclosure of claim 1, wherein the door is shaped such that the door forms a side of the enclosure when closed and is parallel to a surface supporting the enclosure when rotated about the generally vertical axis to a fully opened position.

9. The enclosure of claim 1, further including one or more connectors are disposed in one or more of the slots, the one or more connectors for connecting one or more stored electronic devices to a power supply system and/or network connection system.

10. The enclosure of claim 9, wherein the one or more connectors include pigtail connection connectors.

11. The enclosure of claim 9, wherein the one or more connectors are part of a docking station.

12. The enclosure of claim 11, wherein the docking station connector is configured to connect to an electronic device automatically as the electronic device is positioned into the storage and connection position.

13. An enclosure for storing more than one electronic device, comprising:
a frame having a rear surface to be in apposition to a support surface;
a rack supported within the frame, the racking having at least one slot for receiving an electronic device, the slot being accessible through a side of the enclosure when an enclosure door is in the open position; and
one or more connectors disposed in one or more of the at least one slots, the one or more connectors for connecting one or more stored electronic devices to a power supply system and/or network connection system.

14. The enclosure of claim 13, wherein the one or more connectors include pigtail connection connectors.

15. The enclosure of claim 13, wherein the one or more connectors are part of a docking station.

16. The enclosure of claim 15, wherein the docking station connector is configured to connect to an electronic device automatically as the electronic device is positioned into the storage and connection position.

17. The enclosure of claim 13, wherein the door is supported by the frame and pivotable about a generally vertical axis between a closed position substantially perpendicular to the rear surface and an open position substantially planar with the rear surface.

18. The enclosure of claim 17, further comprising a coupling connected to the door and to the rack, the coupling configured for retracting the rack into the enclosure when the door is closed and extracting at least a portion of the rack out of the enclosure when the door is opened, the rack traveling substantially linearly in a plane parallel to the rear surface.

19. The enclosure of claim 13, including more than one slot, wherein the slots are at least partially overlapping.

20. The enclosure of claim 13, wherein the at least one slot is configured to receive a device from a generally lateral direction.
